(19) United States
(12) Patent Application Publication
(10) Pub. No.: US 2026/0097352 A1
(43) Pub. Date: Apr. 9, 2026

(54) DEVICES AND SYSTEMS FOR ADVANCED PURIFICATION AND RELATED METHODS

(71) Applicant: ENTEGRIS, INC., Billerica, MA (US)

(72) Inventors: Robert L. Wright, JR., Newtown, CT (US); Lucas B. Henderson, Danbury, CT (US); Bryan C. Hendrix, Danbury, CT (US); David M. Ermert, Danbury, CT (US); Rocky Dean Gipson, Arroyo Grande, CA (US)

(21) Appl. No.: 19/349,761

(22) Filed: Oct. 3, 2025

Related U.S. Application Data
(60) Provisional application No. 63/703,879, filed on Oct. 4, 2024.

(51) Int. Cl. B01D 53/04; C23C 16/448

(52) U.S. Cl. CPC B01D 53/0446; C23C 16/4485; B01D 2257/2045; B01D 2257/80; B01D 2259/45

(57) ABSTRACT

Devices systems for the advanced purification of precursor material and related methods are provided. A vessel assembly comprises a vessel. The vessel is configured to contain a precursor material. The precursor material comprises at least one impurity. The vessel assembly comprises a sorbent medium. When the precursor material is vaporized to obtain a vaporized precursor comprising the at least one impurity, the sorbent medium is contained in the vessel in a location that is in a flow path of the vaporized precursor. The sorbent medium is configured to sorb the at least one impurity.

### FIELD

The present disclosure relates to devices and systems for advanced purification and related methods.

### CROSS-REFERENCE TO RELATED APPLICATIONS

This application claims the benefit under 35 USC 119 of U.S. Provisional Ser. No. 63/703,879 , filed Oct. 4, 2024, the disclosure of which is hereby incorporated herein by reference in its entirety.

### BACKGROUND

Vapor deposition processes can involve delivering purified precursors to tools.

### SUMMARY

Some embodiments relate to a vessel assembly. In some embodiments, the vessel assembly comprises a vessel. In some embodiments, the vessel is configured to contain a precursor material. In some embodiments, the precursor material comprises at least one impurity. In some embodiments, the vessel assembly comprises a sorbent medium. In some embodiments, when the precursor material is vaporized to obtain a vaporized precursor comprising the at least one impurity, the sorbent medium is contained in the vessel in a location that is in a flow path of the vaporized precursor. In some embodiments, the sorbent medium is configured to sorb the at least one impurity.

Some embodiments relate to a system. In some embodiments, the system comprises a first vessel. In some embodiments, the first vessel defines a first volume. In some embodiments, the first vessel is configured to contain a precursor material. In some embodiments, the precursor material comprises at least one impurity. In some embodiments, the system comprises a second vessel fluidly connected to the first vessel. In some embodiments, the second vessel defines a second volume. In some embodiments, the second vessel is configured such that, when the at least one impurity is vaporized in the first vessel to obtain an impurity vapor, the impurity vapor is present in the first volume and the second volume. In some embodiments, the system comprises a sorbent medium contained in the second vessel. In some embodiments, the sorbent medium is configured to sorb the impurity vapor.

Some embodiments relate to a method. In some embodiments, the method comprises obtaining a first vessel defining a first volume. In some embodiments, the first vessel comprises a precursor material. In some embodiments, the precursor material comprises at least one impurity. In some embodiments, the method comprises obtaining a second vessel defining a second volume. In some embodiments, the second vessel comprises a sorbent medium. In some embodiments, the method comprises heating the precursor material to vaporize the at least one impurity to obtain an impurity vapor in the first volume and the second volume. In some embodiments, the sorbent medium sorbs the impurity vapor.

### BRIEF DESCRIPTION OF THE DRAWINGS

FIG. 1 is a schematic diagram of a cross-section of a vessel assembly, according to some embodiments.

FIG. 2 is a schematic diagram of a system with a branched second vessel, according to some embodiments.

FIG. 3 is a schematic diagram of a system with an in-line second vessel, according to some embodiments.

FIG. 4 is a flowchart of a method for purifying a precursor material, according to some embodiments.

FIG. 5 is a graphical representation of the absorbance of impurities in a precursor material, MoO₂Cl₂, according to some embodiments.

FIG. 6 is a graphical representation of the decrease of total pressure in the first vessel, according to some embodiments.

FIG. 7 is a graphical representation of the decrease of total pressure in the first vessel, according to some embodiments.

FIG. 8 is a schematic diagram of a system with an in-line valve according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “halide”refers to a —Cl, —Br, —I, or —F.

As used herein, the term “metal” refers to at least one of an alkali metal, an alkaline earth metal, a transition metal, a post-transition metal, or any combination thereof. In some embodiments, the metal comprises a metal cation. In some embodiments, the metal cation comprises at least one of a lithium cation, a sodium cation, a potassium cation, a rubidium cation, a cesium cation, a francium cation, a beryllium cation, a magnesium cation, a calcium cation, a strontium cation, a barium cation, a radium cation, a scandium cation, a titanium cation, a vanadium cation, a chromium cation, a manganese cation, an iron cation, a cobalt cation, a nickel cation, a copper cation, a zinc cation, a yttrium cation, a zirconium cation, a niobium cation, a molybdenum cation, a technetium cation, a ruthenium cation, a rhodium cation, a palladium cation, a silver cation, a cadmium cation, a hafnium cation, a tantalum cation, a tungsten cation, a rhenium cation, an osmium cation, an iridium cation, a platinum cation, a gold cation, a mercury cation, an aluminum cation, a gallium cation, an indium cation, tin cation, a thallium cation, a lead cation, a bismuth cation, a polonium cation, or any combination thereof. The charge(s) of the metal cations are known and, for simplicity, thus are not repeated here; however, it will be appreciated that the metal cations can have any known charge.

Delivery of precursor material to a tool without precursor particles, precursor impurity vapors and other corrosive vapors may be achieved on-site at a user facility or prior to delivery of an ampoule to the user facility. The ampoules may contain components that makes advance purification more difficult or time consuming. Additionally, ampoules may be high-filled to maximize the solid volume within the ampoule that also contribute to challenges with advanced purification. Some embodiments provided herein overcome at least these challenges by providing devices, systems, and related methods for advanced purification. The devices, systems, and related methods provided herein reduce precursor particles, precursor impurity vapor and other corrosive vapors in an ampoule prior to delivery to a tool.

Some embodiments relate to a vessel assembly. In some embodiments, the vessel assembly comprises a vessel. In some embodiments, the vessel is a pressure-regulated vessel. Non-limiting examples of such other vessels include, without limitation, a pressure-regulated vessel including an internal gas pressure regulator, such as, for example, those of a type commercially available from Entegris, Inc. (Billerica, Mass., USA) under the trademark VAC (Vacuum Actuated Cylinder) or trademark SDS (Safe Delivery First); a pressure-regulated vessel including an internal gas pressure regulator, such as, for example, those of a type as commercially available from Entegris, Inc. (Billerica, Mass., USA) under the trademark VaporSorb; other vessels, such as, for example, those of a type commercially available from Entegris, Inc. (Billerica, Mass., USA) under the trademark ProE-Vap.

In some embodiments, the vessel is configured to contain a precursor material. In some embodiments, the precursor material comprises at least one impurity. In some embodiments, the at least one impurity comprises at least one of a water, a hydrogen chloride (HCl), or any combination thereof. In some embodiments, the at least one impurity comprises a water. In some embodiments, the at least one impurity comprises a HCl.

In some embodiments, the precursor material comprises at least one of a metal halide, a metal oxide, a metal oxyhalide, or any combination thereof. In some embodiments, the precursor material comprises a metal halide. In some embodiments, the precursor material comprises a metal oxide. In some embodiments, the precursor material comprises a metal oxyhalide.

In some embodiments, the precursor material comprises at least one of a molybdenum dichloride dioxide (MoO₂Cl₂), a molybdenum pentachloride (MoCl₅), a molybdenum oxytetrachloride (MoOCl₄), a tungsten pentachloride (WCl₅), a tungsten hexachloride (WCl₆), a tungsten oxytetrachloride (WOCl₄), an aluminum trichloride (AlCl₃), a zirconium tetrachloride (ZrCl₄), a hafnium tetrachloride (HfCl₄), a titanium tetrachloride (TiCl₄), a silicon tetrachloride (SiCl₄), a niobium pentachloride (NbCl₅), a tantalum pentachloride (TaCl₅), a gallium trichloride (GaCl₃), a bismuth trichloride (BiCl₃), or any combination thereof. In some embodiments, the precursor material comprises a molybdenum dichloride dioxide. In some embodiments, the precursor material comprises a molybdenum pentachloride. In some embodiments, the precursor material comprises a molybdenum oxytetrachloride. In some embodiments, the precursor material comprises a tungsten pentachloride. In some embodiments, the precursor material comprises a tungsten hexachloride. In some embodiments, the precursor material comprises a tungsten oxytetrachloride. In some embodiments, the precursor material comprises an aluminum trichloride. In some embodiments, the precursor material comprises a zirconium tetrachloride. In some embodiments, the precursor material comprises a hafnium tetrachloride. In some embodiments, the precursor material comprises a titanium tetrachloride. In some embodiments, the precursor material comprises a silicon tetrachloride.

In some embodiments, the vessel comprises a sorbent medium. In some embodiments, when the precursor material is vaporized to obtain a vaporized precursor comprising the at least one impurity, the sorbent medium is contained in the vessel in a location that is in a flow path of the vaporized precursor. In some embodiments, the vessel location is in a branched position in the flow path of the vaporized precursor. In some embodiments, the vessel location is in an in-line position in the flow path of the vaporized precursor.

In some embodiments, the sorbent medium is configured to sorb the at least one impurity.

In some embodiments, the sorbent medium comprises at least one of a physical absorbent, a chemical absorbent, a reactive material, or any combination thereof.

In some embodiments, the sorbent medium comprises a physical absorbent. In some embodiments, the sorbent medium may be at least one of a zeolite, a metal organic framework, an alumina, or any combination thereof. In some embodiments, the sorbent medium is a zeolite. In some embodiments, the sorbent medium is a metal organic framework. In some embodiments, the sorbent medium is an alumina.

In some embodiments, the zeolite is at least one of a 3A sieve, a 4A sieve, a 5A sieve, or any combination thereof. In some embodiments, the zeolite is a 3A sieve. In some embodiments, the zeolite is a 4A sieve. In some embodiments, the zeolite is a 5A sieve.

The at least one of the zeolite, the metal organic framework, the alumina, or any combination thereof, may be non-limiting examples of a physical absorbent. In some embodiments, the physical absorbent may bind hydrogen chloride to remove the hydrogen chloride from the precursor material.

In some embodiments, the sorbent medium comprises a metal-organic framework. Metal-organic-framework (MOF) adsorbent materials exhibit various physical and molecular forms. Metal-organic frameworks are organic-inorganic hybrid crystalline porous materials that have molecular structures that include a regular repeating array of positively charged metal ions surrounded by organic “linker” molecules. The metal ions form nodes that bind the arms of the organic linker molecules together to form a repeating, hollow cage-like structure. Metal organic frameworks (MOFs) are nanoporous materials consisting of organic linkers coordinated to metal ions in crystalline structures.

In some embodiments, the metal-organic framework comprises at least one of a zeolitic imidazolate frameworks (ZIF), a Carboxylate-based MOF, a Zirconium-based MOF, or any combination thereof.

Zeolitic imidazolate frameworks (ZIF) comprise metal (mainly tetrahedral Zn2) bridged by the nitrogen atoms of imidazolate linkers. Zeolitic imidazolate frameworks (ZIF) includes a tetrahedrally-coordinated transition metal such as iron (Fe), cobalt (Co), Copper (Cu), or Zinc (Zn), connected by imidazolate linkers, which may be the same or different within a particular ZIF composition or relative to a single transition metal atom of a ZIF structure. The ZIF structure includes four-coordinated transition metals linked through imidazolate units to produce extended frameworks based on tetrahedral topologies. ZIFs are said to form structural topologies that are equivalent to those found in zeolites and other inorganic microporous oxide materials.

A zeolitic imidazolate framework can be characterized by features that include the type of transition metal (e.g., iron, cobalt, copper, or zinc), the chemistry of the linker (e.g., chemical substituents of the imidazolate units), pore size of the ZIF, surface area of the ZIF, pore volume of the ZIF, among other physical and chemical properties. Dozens (at least 105) of unique ZIF species or structures are known, each having a different chemical structure based on the type of transition metal and the type of linker (or linkers) that make up the framework. Each topology is identified using a unique ZIF designation, e.g., ZIF-1 through ZIF-105. For a description of ZIFs, including particular chemical compositions and related properties of a large number of known ZIF species, see Phan et al., “Synthesis, Structure, and Carbon Dioxide Capture Properties of Zeolitic Imidazolate Frameworks,” Accounts of Chemical Research, 2010, 43 (1), pp 58-67 (Received Apr. 6, 2009).

In some embodiments, the sorbent medium comprises a chemical absorbent. The at least one of a 3A sieve, a 4A sieve, a 5A sieve, or any combination thereof, may be non-limiting examples of a chemical absorbent. In some embodiments, the chemical absorbent may be formed by melting in the presence of a 3A sieve. In some embodiments, the chemical absorbent may be formed by adding HCl or water into a getter to react with molybdenum trioxide, for example. The reaction may produce the molybdenum dioxide or molybdenum dichloride dioxide. In some embodiments, a bulky amine may be a chemical absorbent used to make an ammonium chloride salt. HCl may be added to the bulky amine to convert the amine to the ammonium chloride salt.

In some embodiments, the sorbent medium comprises a reactive material. In some embodiments, the reactive material may be a molybdenum nitrate, a molybdenum nitrite, a molybdenum trioxide, the 3A sieves, the zeolites, the bulky amine, or any combination thereof. In some embodiments, the molybdenum nitrate may be used as a moly-based HCl getter to consume any produced acid, such as HCl, and limit trace metal content further described herein.

In some embodiments, the chemical absorbent is a reactive material. In some embodiments, the physical absorbent is a reactive material.

In some embodiments, the sorbent medium may be resistant to oxidation from molybdenum. In some embodiments, the sorbent medium may have a high capacity for hydrogen chloride. In some embodiments, the sorbent medium may exhibit selectivity for HCl in the presence of halides and oxyhalides.

In some embodiments, the sorbent medium sorbs the at least one impurity sufficient for the precursor material to obtain a purity of at least 99.9% as measured by IR spectroscopy.

In some embodiments, the vaporized precursor comprises 1% to 99% by volume of a hydrogen chloride based on a total volume of the vaporized precursor, or any range or subrange between 1% and 99%. For example, in some embodiments, the vaporized precursor may be 10% to 90%, 20% to 80%, 30% to 70%, or 40% to 60% by volume of the hydrogen chloride based on a total volume of the vaporized precursor. In some embodiments, the vaporized precursor may be 1% to 90%, 1% to 80%, 1% to 70%, 1% to 60%, 1% to 50%, 1% to 40%, 1% to 30%, 1% to 20%, 1% to 10%, or 1% to 5% by volume of the hydrogen chloride based on a total volume of the vaporized precursor. In some embodiments, the vaporized precursor may be 10% to 99%, 20% to 99%, 30% to 99%, 40% to 99%, 50% to 99%, 60% to 99%, 70% to 99%, 80% to 99%, or 90% to 99% by volume of the hydrogen chloride based on a total volume of the vaporized precursor.

In some embodiments, the vaporized precursor comprises 1% to 99% by volume of a water based on a total volume of the vaporized precursor, or any range or subrange between 1% and 99%. For example, in some embodiments, the vaporized precursor may be 10% to 90%, 20% to 80%, 30% to 70%, or 40% to 60% by volume of the water based on a total volume of the vaporized precursor. In some embodiments, the vaporized precursor may be 1% to 90%, 1% to 80%, 1% to 70%, 1% to 60%, 1% to 50%, 1% to 40%, 1% to 30%, 1% to 20%, 1% to 10%, or 1% to 5% by volume of the water based on a total volume of the vaporized precursor. In some embodiments, the vaporized precursor may be 10% to 99%, 20% to 99%, 30% to 99%, 40% to 99%, 50% to 99%, 60% to 99%, 70% to 99%, 80% to 99%, or 90% to 99% by volume of the water based on a total volume of the vaporized precursor.

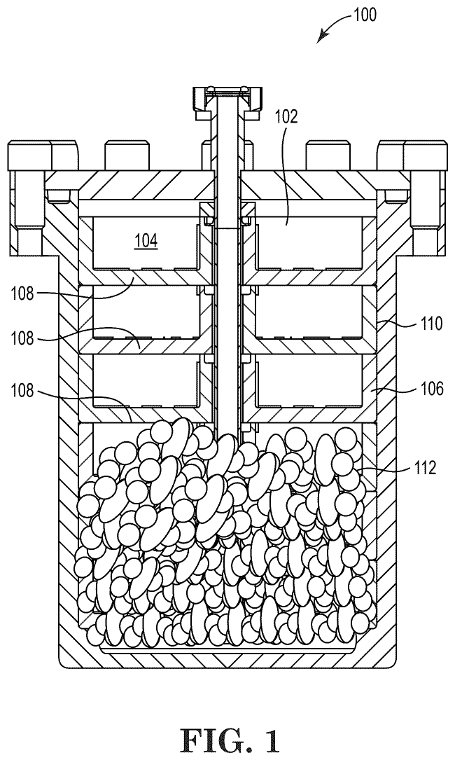

FIG. 1 is a schematic diagram of a cross-section of a vessel assembly, according to some embodiments. The vessel 100 contains a tray assembly 102 and the sorbent medium 112 in an interior volume 104 of the vessel 100. The interior volume 104 has an inner wall surface 106. The tray assembly 102 comprises trays 108, each of which are configured to contain a vapor. Each of the trays 108 of the tray assembly 102 comprises a partition 110 which is configured to be in contact (e.g., thermal contact, physical contact, etc.) with the inner wall surface 106 of the vessel 100. The surface-to-surface contact of the portion 110 with the inner wall surface 106 enhances heat transfer from the vessel 100 to each tray 108 and thus from each tray 108 to the vapor on each tray 308. The sorbent medium 112 sorbs the at least one impurity in the vapor. Various fluid flow paths are defined within the interior volume 104 of the vessel 100 such that a fluid is optionally allowed to flow through the vessel 100 upwards, downwards, or both. The vessel 100 is shown having a generally cylindrical inner chamber. However, it will be appreciated that the interior volume 104 of the vessel assembly may have other shapes without departing from the scope of this disclosure. It will be appreciated that the vessel 100 may not a contain a tray assembly.

Some embodiments relate to a system. In some embodiments, the system comprises a first vessel. In some embodiments, the first vessel defines a first volume. In some embodiments, the first vessel is configured to contain a precursor material. In some embodiments, the precursor material comprises at least one impurity as described herein. In some embodiments the at least one impurity comprises at least one of a water, a HCl, or any combination thereof.

In some embodiments, the system a second vessel fluidly connected to the first vessel. In some embodiments, the second vessel defines a second volume. In some embodiments, the second vessel is configured such that, when the at least one impurity is vaporized in the first vessel to obtain an impurity vapor, the impurity vapor is present in the first volume and the second volume.

In some embodiments, a sorbent medium contained in the second vessel. In some embodiments, the sorbent medium comprises at least one of a physical adsorbent, a chemical absorbent, a reactive material, or any combination thereof. In some embodiments, the sorbent medium comprises at least one of a zeolite, a metal organic framework, an alumina, or any combination thereof.

In some embodiments, the first vessel comprises a second sorbent medium. In some embodiments, the first vessel and the second vessel contain the sorbent medium. In some embodiments, the sorbent medium and the second sorbent medium are the same. In some embodiments, the sorbent medium and the second sorbent medium are not the same.

In some embodiments, the first vessel does not contain the sorbent medium. In some embodiments, the second vessel does not contain the sorbent medium.

In some embodiments, the system further comprises a filter is in fluid communication with the second vessel. In some embodiments, the filter is configured such that the sorbent medium is retained in the second vessel.

In some embodiments, the second vessel provides additional vacant volume for the first vessel in the advanced purification process of the first vessel. In some embodiments, the first vessel is filled with a precursor material near or at maximum volume. At near or maximum volume, the first vessel may not have adequate headspace volume for advanced purification of the first vessel.

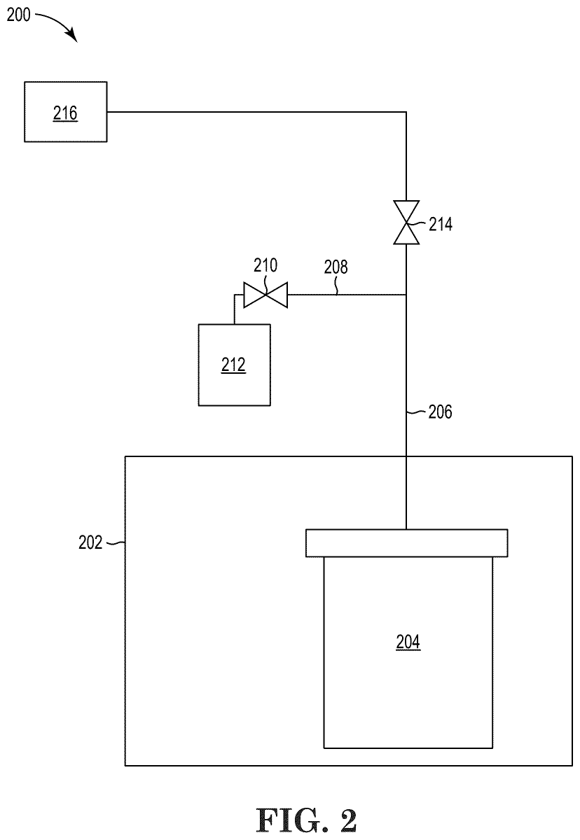

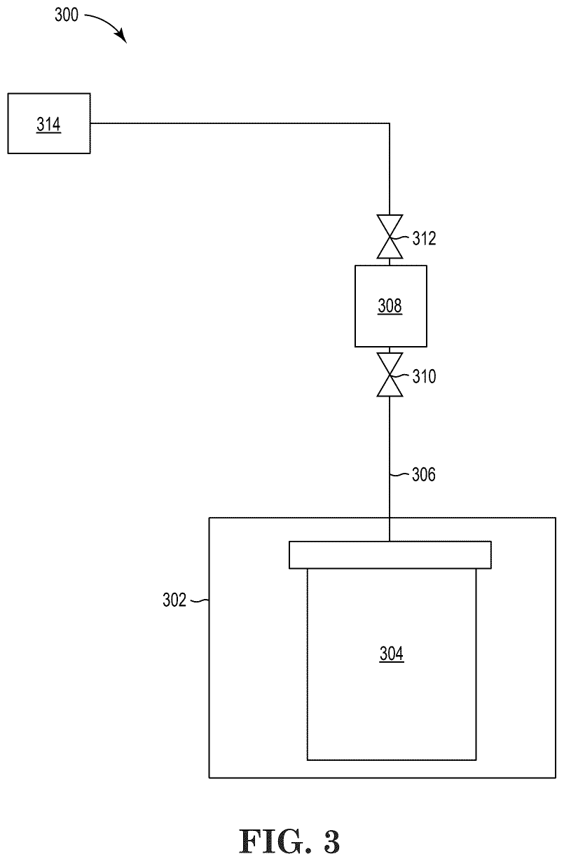

In some embodiments, the second vessel may be located in branched flow path of the first vessel to a semiconductor tool, as in FIG. 2. In some embodiments, the second vessel may be located in an in-line flow path of the first vessel to a semiconductor tool, as in FIG. 3.

FIG. 2 is a schematic diagram of a system with a branched second vessel, according to some embodiments. As shown in FIG. 2, in some embodiments, the system 200 comprises a cabinet 202. In some embodiments, the cabinet 202 comprises a first vessel 204. In some embodiments, the first vessel 204 contains a precursor material in a first volume of the first vessel 204. In some embodiments, the precursor material comprises at least one impurity. In some embodiments, a conduit 206 comprises a branched conduit 208. In some embodiments, the conduit 206 and the branched conduit 208 fluidly connects the first vessel 204 to a second vessel 212. In some embodiments, the second vessel 212 is located in a branch flow path by the branch conduit 208. In some embodiments, the second vessel 212 contains a sorbent medium. In some embodiments, the sorbent medium is configured to sorb an impurity vapor in a second volume of the second vessel 212. In some embodiments, the impurity vapor is obtained by vaporizing the at least one impurity in the first vessel 204. In some embodiments, valves 210, 214, may be configured to direct the impurity vapor from the first vessel to the second volume to sorb the impurity vapor to obtain a purified precursor in the first vessel 204. In some embodiments, valves 210, 214, may be configured to direct the purified precursor from the first volume to a semiconductor tool 216. In some embodiments, the second vessel 212 in a branched configuration, may be a batch process. In some embodiments, the second vessel 212, may contain the at least one impurity without the purified precursor.

FIG. 3 is a schematic diagram of a system with an in-line second vessel, according to some embodiments. As shown in FIG. 3, in some embodiments, the system 300 comprises a cabinet 302. In some embodiments, the cabinet 302 comprises a first vessel 304. In some embodiments, the first vessel 304 contains a precursor material in a first volume of the first vessel 304. In some embodiments, the precursor material comprises at least one impurity. In some embodiments, a conduit 306 fluidly connects the first vessel 304 to a second vessel 308. In some embodiments, the second vessel 308 is located on an in-line flow path with the first vessel 304 by the conduit 208. In some embodiments, the second vessel 308 contains a sorbent medium. In some embodiments, the sorbent medium is configured to sorb an impurity vapor in a second volume of the second vessel 308. In some embodiments, the impurity vapor is obtained by vaporizing the at least one impurity in the first vessel 304. In some embodiments, valves 310, 312, may be configured to direct the impurity vapor from the first volume to the second volume to sorb the impurity vapor to obtain a purified precursor in the second vessel 308. In some embodiments, valves 310, 312, may be configured to direct the purified precursor from the second volume to a semiconductor tool 216. In some embodiments, the second vessel 308 in an in-line configuration, may be a continuous process. In some embodiments, a filter may be downstream of the second vessel 308 to retain the sorbent medium in the second vessel 308.

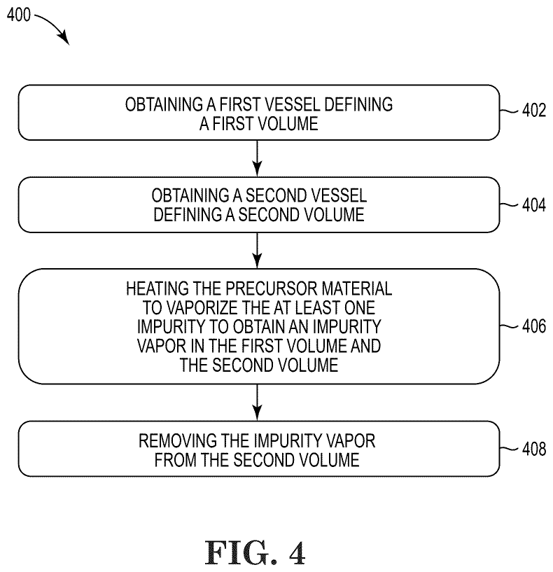

FIG. 4 is a flowchart of a method for purifying a precursor material, according to some embodiments. As shown in FIG. 4, the method may comprise one or more of the following steps: obtaining a first vessel defining a first volume, obtaining a second vessel defining a second volume, heating the precursor material to vaporize the at least one impurity to obtain an impurity vapor in the first volume and the second volume, and removing the impurity vapor from the second volume.

At step 402, in some embodiments, the method comprises providing obtaining a first vessel defining a first volume. In some embodiments, the first vessel comprises a precursor material. In some embodiments, the precursor material comprises at least one impurity. In some embodiments, the at least one impurity comprises at least one of a water, a HCl, or any combination thereof.

In some embodiments, the precursor material comprises at least one of a metal halide, a metal oxide, a metal oxyhalide, or any combination thereof. In some embodiments, the precursor material comprises at least one of a MoO₂Cl₂, a MoCl₅, a MoOCl₄, a WCl₅, a WCl₆, a WOCl₄, an AlCl₃, a ZrCl₄, a HfCl₄, a TiCl₄, a SiCl₄, a NbCl₅, a TaCl₅, a GaCl₃, a BiCl₃, or any combination thereof.

At step 404, in some embodiments, the method comprises obtaining a second vessel defining a second volume. In some embodiments, the second vessel comprises a sorbent medium. In some embodiments, the sorbent medium sorbs the at least one impurity sufficient for the precursor material to obtain a purity of at least 99.9% as measured by IR spectroscopy. In some embodiments, the sorbent medium comprises at least one of a physical adsorbent, a chemical absorbent, a reactive material, or any combination thereof.

At step 406, in some embodiments, the method comprises heating the precursor material to vaporize the at least one impurity to obtain an impurity vapor in the first volume and the second volume. In some embodiments, the vaporizing may comprise heating the first vessel comprising the precursor material. In some embodiments, the vaporizing may comprise heating to a temperature below a decomposition temperature of at least one of the precursor material, the vapor, or any combination thereof.

The first vessel may be heated to a temperature and/or for a duration sufficient to vaporize the at least one impurity. In some embodiments, the first vessel may be heated to a temperature of 50° C. to 300° C., or any range or subrange between 50° C. and 300° C. In some embodiments, the first vessel may be heated to a temperature of 50° C. to 290° C., 50° C. to 280° C., 50° C. to 270° C., 50° C. to 260° C., 50° C. to 250° C., 50° C. to 240° C., 50° C. to 230° C., 50° C. to 220° C., 50° C. to 210° C., 50° C. to 200° C., 50° C. to 190° C., 50° C. to 180° C., 50° C. to 170° C., 50° C. to 160° C., 50° C. to 150° C., 50° C. to 140° C., 50° C. to 130° C., 50° C. to 120° C., 50° C. to 110° C., 50° C. to 100° C., 50° C. to 90° C., 50° C. to 80° C., 50° C. to 70°C., or 50° C. to 60° C. In some embodiments, the vessel may be heated to a temperature of 60° C. to 300° C., 70° C. to 300° C., 80° C. to 300° C., 90° C. to 300° C., 100° C. to 300° C., 100° C. to 250° C., 100° C. to 200° C., 110° C. to 300° C., 120° C. to 300° C., 130° C. to 300° C., 140° C. to 300° C., 150° C. to 300° C., 160° C. to 300° C., 170° C. to 300° C., 180° C. to 300° C., 190° C. to 300° C., 200° C. to 300° C., 210° C. to 300° C., 220° C. to 300° C., 230° C. to 300° C., 240° C. to 300° C., 250° C. to 300° C., 260° C. to 300° C., 270° C. to 300° C., 280° C. to 300° C., or 290° C. to 300° C.

In some embodiments, the first vessel may be configured to control temperature. The temperature of the first vessel may be controlled in any suitable manner. In some embodiments, a thermal jacket for heating and/or cooling is employed around the first vessel. In some embodiments, a ribbon heater is wound around the first vessel. In some embodiments, a block heater having a shape covering at least a major portion of the external surface of the first vessel is employed to heat the first vessel. In some embodiments, a resistive heater is employed to heat the first vessel. In some embodiments, a lamp heater is employed to heat the first vessel. In some embodiments, a heat transfer fluid at elevated temperature may be contacted with the exterior surface of the first vessel, to effect heating and/or cooling thereof. In some embodiments, the heating is conducted by infrared or other radiant energy being impinged on the first vessel. In some embodiments, the first vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

The first vessel may be maintained at the heated temperature for a duration of 30 seconds to 7 days, or any range or subrange between 30 seconds and 7 days. In some embodiments, the vessel may be heated for a duration of 1 minute to 7 days, 1 hour to 7 days, 4 hours to 7 days, 12 hours to 7 days, 24 hours to 7 days, 1 day to 7 days, 2 days to 7 days, 3 days to 7 days, 4 days to 7 days, 5 days to 7 days, 6 days to 7 days, 30 seconds to 6 days, 30 seconds to 5 days, 30 seconds to 4 days, 30 seconds to 3 days, 30 seconds to 2 days, 30 seconds to 1 day, 30 seconds to 12 hours, 30 seconds to 6 hours, 30 seconds to 4 hours, 4 hours to 48 hours, 4 hours to 24 hours, 8 hours to 48 hours, 8 hours to 24 hours, 12 hours to 24 hours, 12 hours to 48 hours, 24 hours to 48 hours, or 36 hours to 48 hours.

The first vessel may be configured to control pressure. The pressure of the vessel may be controlled in any suitable manner. In some embodiments, a gas inlet line may be fluidly coupled to the first vessel. The gas inlet line may be configured to supply a pressurizing gas from a pressurizing gas source to the first vessel. Control of the pressurizing gas into the first vessel may be achieved by at least one of pressure regulators, needle valves, mass flow controllers, downstream pressure controllers, or any combination thereof. In some embodiments, the pressurizing gas comprises an inert gas. In some embodiments, the inert gas comprises at least one of helium, argon, nitrogen, or any combination thereof. In some embodiments, a vacuum line is fluidly coupled to the first vessel. The vacuum line may be configured to apply a vacuum to the first vessel. In some embodiments, the pumping speed is controlled by butterfly valves. It will be appreciated that other mechanisms for controlling the pressure of the vessel may be employed herein without departing from the scope of this disclosure. In some embodiments, the method comprises depressurizing the first vessel. In some embodiments, the method comprises pressurizing the first vessel. In some embodiments, the step of depressurizing and/or the step of pressurizing is performed during the step of heating.

In some embodiments, the first vessel may be pressurized to a pressure of 0.001 Torr to 1000 Torr, or any range or subrange between 0.001 Torr and 1000 Torr. In some embodiments, the first vessel may be depressurized to a pressure of 0.001 Torr to 1000 Torr, or any range or subrange between 0.001 Torr and 1000 Torr. For example, in some embodiments, the first vessel has a pressure of 0.001 Torr to 950 Torr, 0.01 Torr to 900 Torr, 0.1 Torr to 850 Torr, 0.5 Torr to 800 Torr, 1 Torr to 750 Torr, 5 Torr to 700 Torr, 10 Torr to 650 Torr, 50 Torr to 600 Torr, 100 Torr to 550 Torr, 150 Torr to 500 Torr, 200Torr to 450 Torr, 250 Torr to 400 Torr, or 300 Torr to 350 Torr. In some embodiments, the first vessel has a pressure of 0.001 Torr to 950 Torr, 0.001 Torr to 900 Torr, 0.001 Torr to 850 Torr, 0.001 Torr to 800 Torr, 0.001 Torr to 750 Torr, 0.001 Torr to 700 Torr, 0.001 Torr to 650 Torr, 0.001 Torr to 600 Torr, 0.001 Torr to 550 Torr, 0.001 Torr to 500 Torr, 0.001 Torr to 450 Torr, 0.001 Torr to 400 Torr, 0.001 Torr to 350 Torr, 0.001 Torr to 300 Torr, 0.001 Torr to 250 Torr, 0.001 Torr to 200 Torr, 0.001 Torr to 150 Torr, 0.001 Torr to 100 Torr, 0.001 Torr to 50 Torr, 0.001 Torr to 40 Torr, 0.001 Torr to 30 Torr, 0.001 Torr to 20 Torr, 0.001 Torr to 10 Torr, 0.001 Torr to 1 Torr, 0.001 Torr to 0.5 Torr, 0.001 Torr to 0.1 Torr, or 0.001 Torr to 0.01 Torr. In some embodiments, the first vessel has a pressure of 0.01 Torr to 1000 Torr, 0.1 Torr to 1000 Torr, 0.5 Torr to 1000 Torr, 1 Torr to 1000 Torr, 5 Torr to 1000 Torr, 10 Torr to 1000 Torr, 50 Torr to 1000 Torr, 100 Torr to 1000 Torr, 150 Torr to 1000 Torr, 200 Torr to 1000 Torr, 250 Torr to 1000 Torr, 300 Torr to 1000 Torr, 350 Torr to 1000 Torr, 400 Torr to 1000 Torr, 450 Torr to 100 Torr, 500 Torr to 100 Torr, 550 Torr to 100 Torr, 600 Torr to 100 Torr, 650 Torr to 100 Torr, 700 Torr to 100 Torr, 750 Torr to 100 Torr, 800 Torr to 100 Torr, 850 Torr to 100 Torr, 900 Torr to 100 Torr, or 950 Torr to 100 Torr.

In some embodiments, in a batch process, the at least one impurity has a vapor pressure greater than a vapor pressure of the precursor.

At step 408, in some embodiments, the method comprises removing the impurity vapor from the second volume. In some embodiments, removing the impurity vapor comprises sorbing the impurity vapor with the sorbent medium. In some embodiments, removing the impurity comprises pumping the impurity vapor from the second vessel to an exhaust.

Any one or more of the embodiments disclosed herein shall be understood to be combinable without departing from the scope or spirit of the disclosure.

### Example 1—Comparative Example

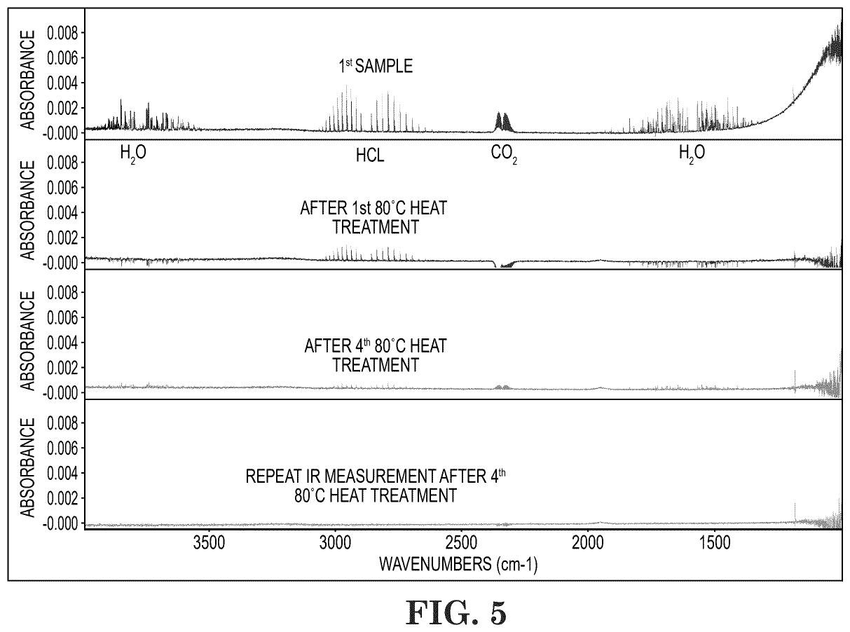

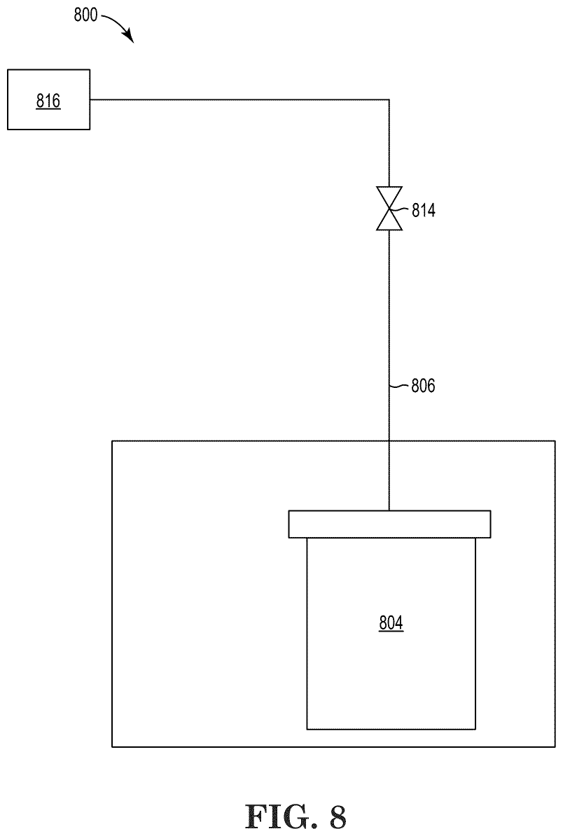

A batch advanced purification process was performed for the purification of a precursor material, MoO₂Cl₂, in a first vessel 804, as shown in FIG. 8. The precursor material was heated to 80° C. in a first cycle to produce an impurity vapor. A portion of the impurity vapor flowed to a second vessel, 816. The remaining precursor material in the first vessel 804 was then measured by IR spectroscopy. The first vessel 804 and second vessel 816 were then cooled, to reverse flow residual precursor material from the second vessel 816 to the first vessel 804. The precursor material was heated again to 80° C. three additional times, cooling after each cycle. The precursor material was then measured by IR spectroscopy. The results are shown in FIG. 5. FIG. 5 is a graphical representation of the absorbance of impurities in a precursor material, MoO₂Cl₂. As shown in FIG. 5, the HCl impurity vapor and water impurity vapor was removed from the precursor material with each cycle run.

### Example 2

A precursor material, MoO₂Cl₂, was placed in a first vessel 304, as shown in FIG. 3. The precursor material was heated to 130° C. to produce a vapor. The vapor contained MoO₂Cl₂ and an impurity vapor, such as HCl. As the vapor flowed through the second vessel 308 containing an absorbent, the impurity vapor was removed. The precursor material was then measured by IR spectroscopy. The results are comparable to the bottom spectrum in FIG. 5. The HCl impurity vapor was removed from the precursor material with each cycle run.

### EXAMPLE 3—Comparative Example

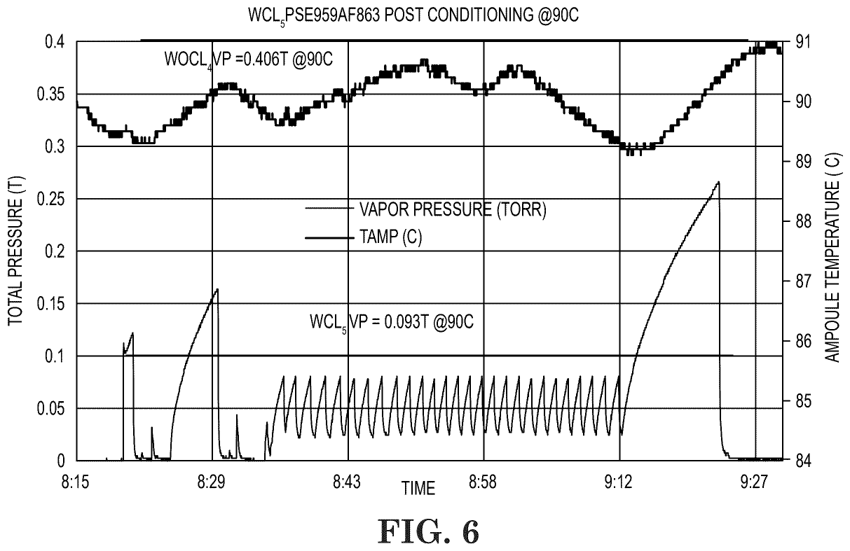

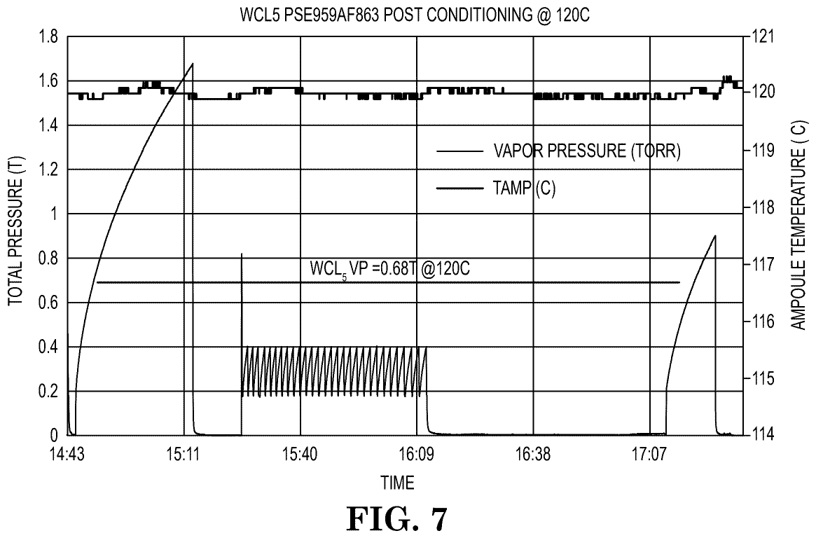

A batch advanced purification process was performed for the purification of a precursor material, WCl₅, in a first vessel 804, as shown in FIG. 8. The precursor material was heated to 135° C. in a first cycle to produce both an impurity vapor and the precursor vapor in the headspace of the first vessel 804. The first vessel 804 was then evacuated through valve 814 to remove all vapors including both precursor vapors and impurity vapors from the first vessel. Valve 814 was then closed so that the precursor vapors and impurity vapors reached equilibrium in the first vessel 804. The cycle was repeated four times by pumping for 1 minute, then pumping four times for 3 minutes, followed by pumping four times for 10 minutes. The results are shown in FIG. 6. FIG. 6 is a graphical representation of the decrease of total pressure in the first vessel 804, according to some embodiments. The total pressure is the sum of the partial pressures of the precursor and impurity. As shown, the impurity vapor decreased with each cycle since the precursor vapor does not change when at equilibrium. FIG. 7 is a graphical representation of the decrease of total pressure in the first vessel 804, according to some embodiments. FIG. 7 shows overlays of each pumping cycle in FIG. 6 to clarify the repeatability.

### Example 4

A precursor material, WCl₅, was placed in a first vessel 204, as shown in FIG. 2. The precursor material was heated to 130° C. to produce a vapor in the headspace of the first vessel and the second vessel 212 with valve 210 in an open position. The vapor contained WCl₅ and an impurity vapor. The first vessel 204 and second vessel 212 were then evacuated through valve 214 in an open position to remove all vapors including both precursor and impurity material from the first vessel 204. After valve 214 was closed, the headspace of the first vessel 204 and the inner volume of the second vessel 212 was refilled with pure precursor vapor, as shown by the last cycle in FIG. 6 and FIG. 7.

### Example 5

A precursor material, WCl₅, was placed in a first vessel 204, as shown in FIG. 2. A sorbent material was placed in a second vessel 212. The precursor material was heated to 130° C. to produce a vapor in the headspace of first vessel 204 and the second vessel 212. The vapor contained WCl₅ and an impurity vapor. The sorbent material in the second vessel 212 sorbed all the impurity vapors from the first vessel 204. Valve 210 was then closed. The pure precursor vapor from the first vessel was then delivered to the process 216.

### Aspects

Various Aspects are described below. It is to be understood that any one or more of the features recited in the following Aspect(s) can be combined with any one or more other Aspect(s).
Aspect 1. A vessel assembly comprising:
   a vessel,
      wherein the vessel is configured to contain a precursor material,
         wherein the precursor material comprises at least one impurity; and
   a sorbent medium,
      wherein, when the precursor material is vaporized to obtain a vaporized precursor comprising the at least one impurity, the sorbent medium is contained in the vessel in a location that is in a flow path of the vaporized precursor,
      wherein the sorbent medium is configured to sorb the at least one impurity.
Aspect 2. The vessel assembly of Aspect 1, wherein the sorbent medium comprises at least one of a physical adsorbent, a chemical absorbent, a reactive material, or any combination thereof.
   Aspect 3. The vessel assembly according to any one of Aspects 1-2, wherein the sorbent medium comprises at least one of a zeolite, a metal organic framework, an alumina, or any combination thereof.
Aspect 4. The vessel assembly according to any one of Aspects 1-3, wherein precursor material comprises at least one of a molybdenum dichloride dioxide (MoO2Cl2), a molybdenum pentachloride (MoCl₅), a molybdenum oxytetrachloride (MoOCl₄), a tungsten pentachloride (WCl₅), a tungsten hexachloride (WCl₆), a tungsten oxytetrachloride (WOCl₄), an aluminum trichloride (AlCl₃), a zirconium tetrachloride (ZrCl₄), a hafnium tetrachloride (HfCl₄), a titanium tetrachloride (TiCl₄), a silicon tetrachloride (SiCl₄), a niobium pentachloride (NbCl₅), a tantalum pentachloride (TaCl₅), a gallium trichloride (GaCl₃), a bismuth trichloride (BiCl₃), or any combination thereof.
Aspect 5. The vessel assembly according to any one of Aspects 1-4, wherein the sorbent medium sorbs the at least one impurity sufficient for the precursor material to obtain a purity of at least 99.9% as measured by IR spectroscopy.
   Aspect 6. The vessel assembly according to any one of Aspects 1-5, wherein the at least one impurity comprises at least one of a water, a HCl, or any combination thereof.
Aspect 7. The vessel assembly according to any one of Aspects 1-6, wherein the precursor material at least one of a metal halide, a metal oxide, a metal oxyhalide, or any combination thereof.
Aspect 8. A system comprising:
   A First Vessel,
      wherein the first vessel defines a first volume,
      wherein the first vessel is configured to contain a precursor material,
         wherein the precursor material comprises at least one impurity;
   a second vessel fluidly connected to the first vessel,
      wherein the second vessel defines a second volume,
      wherein the second vessel is configured such that, when the at least one impurity is vaporized in the first vessel to obtain an impurity vapor, the impurity vapor is present in the first volume and the second volume; and
   a sorbent medium contained in the second vessel,
      wherein the sorbent medium is configured to sorb the impurity vapor.
Aspect 9. The system according to Aspect 8, wherein the first vessel comprises a second sorbent medium.
Aspect 10. The system according to any one of Aspects 8-9, further comprising:
   a filter in fluid communication with the second vessel,
      wherein the filter is configured such that the sorbent medium is retained in the second vessel.
Aspect 11. The system according to any one of Aspects 8-10, wherein the sorbent medium comprises at least one of a physical adsorbent, a chemical absorbent, a reactive material, or any combination thereof.
Aspect 12. The system according to any one of Aspects 8-11, wherein the sorbent medium comprises at least one of a zeolite, a metal organic framework, an alumina, or any combination thereof.
Aspect 13. The system according to any one of Aspects 8-12, wherein precursor material comprises at least one of a molybdenum dichloride dioxide (MoO₂Cl₂), a molybdenum pentachloride (MoCl₅), a molybdenum oxytetrachloride (MoOCl₄), a tungsten pentachloride (WCl₅), a tungsten hexachloride (WCl₆), a tungsten oxytetrachloride (WOCl₄), an aluminum trichloride (AlCl₃), a zirconium tetrachloride (ZrCl₄), a hafnium tetrachloride (HfCl₄), a titanium tetrachloride (TiCl₄), a silicon tetrachloride (SiCl₄), a niobium pentachloride (NbCl₅), a tantalum pentachloride (TaCl₅), a gallium trichloride (GaCl₃), a bismuth trichloride (BiCl₃), or any combination thereof.
Aspect 14. The system according to any one of Aspects 8-13, wherein the at least one impurity comprises at least one of a water, a HCl, or any combination thereof.
Aspect 15. A method comprising:
   obtaining a first vessel defining a first volume,
      wherein the first vessel comprises a precursor material,
         wherein the precursor material comprises at least one impurity;
   obtaining a second vessel defining a second volume,
      wherein the second vessel comprises a sorbent medium; and heating the precursor material to vaporize the at least one impurity to obtain an impurity vapor in the first volume and the second volume,
      wherein the sorbent medium sorbs the impurity vapor.
Aspect 16. The method according to Aspect 15, wherein the sorbent medium sorbs the impurity vapor sufficient to obtain a precursor material with a purity of at least 99.9% as measured by IR spectroscopy.
Aspect 17. The method according to any one of Aspects 15-16, wherein the sorbent medium comprises at least one of a physical adsorbent, a chemical absorbent, a reactive material, or any combination thereof.
Aspect 18. The method according to any one of Aspects 15-17, wherein the sorbent medium comprises at least one of a zeolite, a metal organic framework, an alumina, or any combination thereof.
Aspect 19. The method according to any one of Aspects 15-18, wherein precursor material comprises at least one of a molybdenum dichloride dioxide (MoO₂Cl₂), a molybdenum pentachloride (MoCl₅), a molybdenum oxytetrachloride (MoOCl₄), a tungsten pentachloride (WCl₅), a tungsten hexachloride (WCl₆), a tungsten oxytetrachloride (WOCl₄), an aluminum trichloride (AlCl₃), a zirconium tetrachloride (ZrCl₄), a hafnium tetrachloride (HfCl₄), a titanium tetrachloride (TiCl₄), a silicon tetrachloride (SiCl₄), a niobium pentachloride (NbCl₅), a tantalum pentachloride (TaCl₅), a gallium trichloride (GaCl₃), a bismuth trichloride (BiCl₃), or any combination thereof.
Aspect 20. The method according to any one of Aspects 15-19, wherein the at least one impurity comprises at least one of a water, a HCl, or any combination thereof.

What is claimed is:

1. A vessel assembly comprising:
a vessel,
wherein the vessel is configured to contain a precursor material,
wherein the precursor material comprises at least one impurity; and
a sorbent medium,
wherein, when the precursor material is vaporized to obtain a vaporized precursor comprising the at least one impurity, the sorbent medium is contained in the vessel in a location that is in a flow path of the vaporized precursor,
wherein the sorbent medium is configured to sorb the at least one impurity.

2. The vessel assembly of claim 1, wherein the sorbent medium comprises at least one of a physical adsorbent, a chemical absorbent, a reactive material, or any combination thereof.

3. The vessel assembly of claim 1, wherein the sorbent medium comprises at least one of a zeolite, a metal organic framework, an alumina, or any combination thereof.

4. The vessel assembly of claim 1, wherein precursor material comprises at least one of a molybdenum dichloride dioxide (MoO₂Cl₂), a molybdenum pentachloride (MoCl₅), a molybdenum oxytetrachloride (MoOCl₄), a tungsten pentachloride (WCl₅), a tungsten hexachloride (WCl₆), a tungsten oxytetrachloride (WOCl₄), an aluminum trichloride (AlCl₃), a zirconium tetrachloride (ZrCl₄), a hafnium tetrachloride (HfCl₄), a titanium tetrachloride (TiCl₄), a silicon tetrachloride (SiCl₄), a niobium pentachloride (NbCl₅), a tantalum pentachloride (TaCl₅), a gallium trichloride (GaCl₃), a bismuth trichloride (BiCl₃), or any combination thereof.

5. The vessel assembly of claim 1, wherein the sorbent medium sorbs the at least one impurity sufficient for the precursor material to obtain a purity of at least 99.9% as measured by IR spectroscopy.

6. The vessel assembly of claim 1, wherein the at least one impurity comprises at least one of a water, a HCl, or any combination thereof.

7. The vessel assembly of claim 1, wherein the precursor material comprises at least
one of a metal halide, a metal oxide, a metal oxyhalide, or any combination thereof

8. A system comprising:
a first vessel,
wherein the first vessel defines a first volume,
wherein the first vessel is configured to contain a precursor material,
wherein the precursor material comprises at least one impurity;
a second vessel fluidly connected to the first vessel,
wherein the second vessel defines a second volume,
wherein the second vessel is configured such that, when the at least one impurity is vaporized in the first vessel to obtain an impurity vapor, the impurity vapor is present in the first volume and the second volume; and
a sorbent medium contained in the second vessel,
wherein the sorbent medium is configured to sorb the impurity vapor.

9. The system of claim 8, wherein the first vessel comprises a second sorbent medium.

10. The system of claim 8, further comprising:
a filter in fluid communication with the second vessel,
wherein the filter is configured such that the sorbent medium is retained in the second vessel.

11. The system of claim 8, wherein the sorbent medium comprises at least one of a physical adsorbent, a chemical absorbent, a reactive material, or any combination thereof.

12. The system of claim 8, wherein the sorbent medium comprises at least one of a zeolite, a metal organic framework, an alumina, or any combination thereof.

13. The system of claim 8, wherein the precursor material comprises at least one of a molybdenum dichloride dioxide (MoO₂Cl₂), a molybdenum pentachloride (MoCl₅), a molybdenum oxytetrachloride (MoOCl₄), a tungsten pentachloride (WCl₅), a tungsten hexachloride (WCl₆), a tungsten oxytetrachloride (WOCl₄), an aluminum trichloride (AlCl₃), a zirconium tetrachloride (ZrCl₄), a hafnium tetrachloride (HfCl₄), a titanium tetrachloride (TiCl₄), a silicon tetrachloride (SiCl₄), a niobium pentachloride (NbCl₅), a tantalum pentachloride (TaCl₅), a gallium trichloride (GaCl₃), a bismuth trichloride (BiCl₃), or any combination thereof.

14. The system of claim 8, wherein the at least one impurity comprises at least one of a water, a HCl, or any combination thereof.

15. A method comprising:
obtaining a first vessel defining a first volume,
wherein the first vessel comprises a precursor material,
wherein the precursor material comprises at least one impurity;
obtaining a second vessel defining a second volume,
wherein the second vessel comprises a sorbent medium; and
heating the precursor material to vaporize the at least one impurity to obtain an impurity vapor in the first volume and the second volume,
wherein the sorbent medium sorbs the impurity vapor.

16. The method of claim 15, wherein the sorbent medium sorbs the impurity vapor sufficient to obtain a precursor material with a purity of at least 99.9% as measured by IR spectroscopy.

17. The method of claim 15, wherein the sorbent medium comprises at least one of a physical adsorbent, a chemical absorbent, a reactive material, or any combination thereof.

18. The method of claim 15, wherein the sorbent medium comprises at least one of a zeolite, a metal organic framework, an alumina, or any combination thereof.

19. The method of claim 15, wherein precursor material comprises at least one of a molybdenum dichloride dioxide (MoO₂Cl₂), a molybdenum pentachloride (MoCl₅), a molybdenum oxytetrachloride (MoOCl₄), a tungsten pentachloride (WCl₅), a tungsten hexachloride (WCl₆), a tungsten oxytetrachloride (WOCl₄), an aluminum trichloride (AlCl₃), a zirconium tetrachloride (ZrCl₄), a hafnium tetrachloride (HfCl₄), a titanium tetrachloride (TiCl₄), a silicon tetrachloride (SiCl₄), a niobium pentachloride (NbCl₅), a tantalum pentachloride (TaCl₅), a gallium trichloride (GaCl₃), a bismuth trichloride (BiCl₃), or any combination thereof.

20. The method of claim 15, wherein the at least one impurity comprises at least one of a water, a HCl, or any combination thereof.
